(19) United States
(12) Patent Application Publication
(10) Pub. No.: US 2006/0055285 A1
(43) Pub. Date: Mar. 16, 2006

(54) Method and devices for driving a body

(76) Inventors: Theodorus Jacobus A De Vries, Enschede (NL); Herman Daniel Kloppenburg, Noorduolde Fr (NL); Jan Peters, Apeldoorn (NL); Frank Alexander Van Den Bovenkamp, Enshede (NL)

Correspondence Address: BOZICEVIC, FIELD & FRANCIS LLP, 1900 UNIVERSITY AVENUE, SUITE 200, EAST PALO ALTO, CA, 94303, US

(21) Appl. No.: 10/496,331

(22) PCT Filed: Nov. 24, 2002
(86) PCT No.: PCT/NL02/00760

§ 371 Date: Jul. 21, 2005

(30) Foreign Application Priority Data
Nov. 23, 2001 (NL) 1019424
Nov. 1, 2002 (NL) 1021810

(51) Int. Cl. H01L 41/08

(52) U.S. Cl. 310/328

(57) ABSTRACT

The invention relates to a method for relative driving of bodies on the basis of electromagnetic or piezo-electrical conversion of electricity into energy and/or movement. Use is made of intermediate bodies for the conversion into mechanical energy. The invention also relates to a linear drive assembly for a shaft or other elongate body, with engaging means for co-displacing engagement of the shaft and the like, as well as displacing means forming a moving whole with the engaging means for displacing the engaging means in driving direction between a non-engaging or slipping position and an engaging or shaft-co-displacing position. Means are further provided for displacing the displacing means in driving direction. In addition, the invention relates to a device comprising two drives assemblies according to the invention, wherein the drive assemblies are disposed for moving the shaft in opposite directions.

The present invention relates to a method for converting electrical energy into mechanical energy. This conversion has the purpose, using minimal assist means and provisions, of obtaining an actuator of the correct specifications at a favourable cost price. Particularly envisaged here is a linear or rotational actuator, which can be provided with power supply via simple electricity cables and which can produce the required displacement or force without other means.

In the current practice of mechanical engineering and motion technology there are different solutions for the different driving problems. Broadly speaking, the classes of available drive systems are hydraulic, pneumatic and/or electromagnetic drives.

In hydraulics there is the problem of the use of oil, which is often considered undesirable for environmental reasons. A further drawback is the low efficiency (<50%), while on the other hand it has a very high energy density. Very great forces can also be achieved herewith in relatively simple manner.

In pneumatics use is made of compressed air to drive cylinders. The necessity for a compressed air provision is a great drawback here. Such a provision is already available at many industrial locations, but it is very expensive (also in use). The particular necessity of obtaining such an installation and (per machine) the accessories for air treatment makes large demands on the budget. It has a low efficiency and produces much noise nuisance. The venting of air which still contains oil also forms a problem in different branches of industry, such as the medical industry, food industry, printing industry, textile industry and the like.

In electromechanical motion technology there are many types of drive which are very well suited for a plurality of applications. In the ‘lower segment’ of the market however, there is no advantageous solution for the frequently occurring ‘direct-drive’ requirements of industry. ‘Pick and place’ applications and adjustment options can be envisaged here. Much applied for this purpose is pneumatics using a fixed stop, which produces two positions. The spindle drive is also a very common one. This latter is a relatively expensive solution.

In respect of minimizing the economic and ecological cost of the use of actuators, an actuator is sought with a high efficiency and a low cost price. The present invention has for its object to enable the production at this low cost price of an actuator with a low ecological impact. The solution must be reliable and inexpensive, in addition to which it must comply with reasonable specifications. It is important for this purpose that the solution is simple, whereby the reliability and the low cost price can be combined.

The low cost price results from the use of relatively simple means, though in a manner whereby relatively high performance can be achieved therewith. An example hereof is the use of simple clamping mechanisms for fixing the intermediate bodies and the body for driving, for instance a drive shaft. These can be produced in simple and inexpensive manner and exhibit hardly any hysteresis in their operation. This is partly due to a relatively great rigidity, whereby less step loss occurs, and the fact that no relative movements are allowed at the moment of force transmission. Two types of these clamping mechanisms can be distinguished, viz. unilateral clamping and bilateral clamping.

Further advantage is achieved from buffering energy, whereby energy supply can be performed intermittently and efficiently while emission takes place uniformly. For this purpose the current transmission through the coils of an electromagnetic converter can be limited to a peak of limited height and width.

The invention also provides a method whereby the electrically generated force contains both an active and a reactive force. It is hereby possible during charging of one of the buffers to have the force produced by this buffer to be temporarily produced by an adjacent intermediate body. A more uniform force and speed profile is hereby obtained with a higher efficiency. Owing to the invention this force coupling is also such that the mechanism continues to operate in the same manner, without being influenced by the position relative to the housing. This is possible because a coil is fixed in the housing and because the force-generating gap between two intermediate bodies is freely movable relative to the coil. In the case of a piezo-actuation, the piezo-element will exert a force between both bodies, without the position relative to the housing having to be fixed hereby. A higher efficiency can be achieved by this (relative) driving not dependent on position.

A variety of forms are possible as embodiments of the actuator described in this invention. A linear actuator with the outward appearance of a pneumatic cylinder can be envisaged. This takes a slender form for the time being. But the principle also lends itself for an embodiment in a shorter version with a larger diameter.

In the rotational variant a choice can also be made between a long version with small diameter and vice versa. The rotational variant is particularly suitable where relatively large torques are required at relatively low powers and speeds. This ‘direct-drive’ actuator is highly suitable here owing to a compact installation and the absence of a reductor.

At the moment that two (or more) intermediate bodies make a movement relative to each other, in the case of unidirectional blocking the one intermediate body will make a relative movement relative to the body for driving, while conversely the other intermediate body will co-displace it. When the relative movement is reversed, this will take place the other way round. Using the energy buffering, both these intermediate bodies will as it were charge themselves and ultimately relinquish this energy to the body for driving.

In the case of a bilateral clamping mechanism, the control will ensure that the choice for co-displacing the body for driving and the relative movement take place in a manner and with a timing such that a uniform movement and efficient force transfer will take place.

The present invention has for its object to provide a method of the type described in claims 1 and following, whereby it is possible to supply a particular market segment in motion technology with a low-cost actuator.

It is noted that a device as intended in U.S. Pat. No. 5,055,725 is not very powerful because the total driving force can be drawn only from the diverted magnetic field. Nor are there intermediate bodies present. The clamping mechanisms do not operate in the drive.

The tilting plate mentioned in patent GB 2 285 711 forms a whole and can therefore not be used to buffer energy as in the present invention. The same applies to U.S. Pat. No. 5,315,202, which operates with the same glue-clamp-like construction.

Patent DE 32 33 759 makes use of balls in a conical bush. This results in much hysteresis, whereby the efficiency of the utilized energy becomes very low. The clamping and driving principle are also both embodied in this manner, each having available its own ‘drive coil’.

The mechanism in U.S. Pat. No. 3,445,689 is based on a pivoting movement about a mounted shaft transversely of the direction of movement, whereby a plunger co-displaces a shaft situated therein under the influence of a magnetic force. This in contrast to the axial translations proposed by this invention.

Finally, patent DE 43 29 163 is an invention based on the use of piezo-electrical driving. This embodiment does not however have any possibility of allowing homogeneous movement of the body for driving, here a shaft. Nor is there any possibility of controlling speed or force, and the clamping device described here is subject to wear and hysteresis.

The invention also relates to a linear drive assembly, and the international designation “Linear Shaft Driver” can also be applicable.

Linear drives are applied for displacing a shaft in a longitudinal direction. Such a shaft can form a rigid body with which normal forces for driving another object are transferred. Another embodiment of such a shaft is that of a guide for an operating means. Usual linear drives, in particular those operating hydraulically or pneumatically, are rather bulky and/or susceptible to malfunction, and insufficiently precise due to the displacement options of the components relative to each other, certainly after a period of time.

An object of the invention is to make improvements herein. In the simplest embodiment the invention provides a fully controllable, double-acting linear drive on the basis of only two electromagnets.

In one aspect the invention provides for this purpose a linear drive assembly for a shaft or other elongate body, comprising engaging means for co-displacing engagement of the shaft and the like, as well as displacing means situated outside the shaft and forming a moving whole with the engaging means for displacing the engaging means in driving direction between a non-engaging or slipping position and an engaging or shaft-co-displacing position, further comprising means for displacing the displacing means in driving direction.

Such a drive can operate directly and is thereby accurate. The space occupied can herein remain small. The displacing means are preferably adapted to exert a pushing force on the engaging means in the driving direction, whereby engagement with the shaft can take place as quickly as possible.

The engaging means preferably comprise shoes provided with engaging surfaces which engage the shaft, as well as preferably resilient arms which extend radially and counter to the driving direction of the shoes and which connect the shoes to the displacing means. By exerting a force on the arms in driving direction, the pressing force of the shoes on the shaft will be greatly increased, whereafter the friction force of the shoes on the shaft is sufficiently strong for clamping co-displacement of the shaft by the shoes and thereby by the engaging means. The arms are herein preferably connected movably, in particular rotatably or tiltably, to the displacing means.

In order to speed up realization of the engaging contact of the shoes with the shaft, it is advantageous if the shoes are at all times held close to the shaft by means of a revolving belt. The compactness of the drive assembly and the reliability of operation are enhanced if this latter is further preferably provided with an electromagnet for energizing the displacing means. Energizing lines can herein be kept simple, in particular be limited to electrical cables. The displacing means and drive means are herein preferably received in a holder, such as a housing, which is disposed slidably in shaft direction. It can also comprise ferromagnetic material. In advantageous manner means can herein be present, preferably at least one electromagnet—or alternatively a spring—, for moving back the holder, in particular the displacing means, counter to the drive direction relative to the shaft.

In order to prevent a slide-back movement of the shaft, it is recommended that the drive assembly is further provided with preferably stationary second means for retaining the shaft in a return movement, which retaining means preferably comprise shoes and arms comparable to the drive means.

These retaining means preferably act passively on the shaft, wherein means are present for de-activating retaining means, preferably electromagnetic means.

In order to enhance the return movement of the drive assembly, it is recommended that the means for de-activating comprise means for reducing the contact pressure of the shoes against the shaft. In order to enable driving in two directions, there is provided that the drive assembly comprises two drive assemblies as described, wherein the drive assemblies are disposed for driving of the shaft in opposite directions. It is also recommended herein that means are provided for de-activating the displacing means, preferably electromagnetic means, during a return stroke.

In another aspect the invention provides a linear drive assembly for a shaft or other elongate body, comprising engaging means for co-displacing engagement of the shaft and the like, further comprising controllable (electromagnetically acting) means for displacing the engaging means in driving direction.

The drive assembly further preferably comprises controllable (electromagnetically acting) means for releasing the drive means from the shaft.

The drive assembly further preferably comprises controllable (electromagnetically acting) means for fixing the shaft.

Stated and other features of the method and devices of the invention will be further elucidated hereinbelow on the basis of a number of embodiments. Reference is herein made to the drawings, in which corresponding components are designated with corresponding reference codes, and in which:

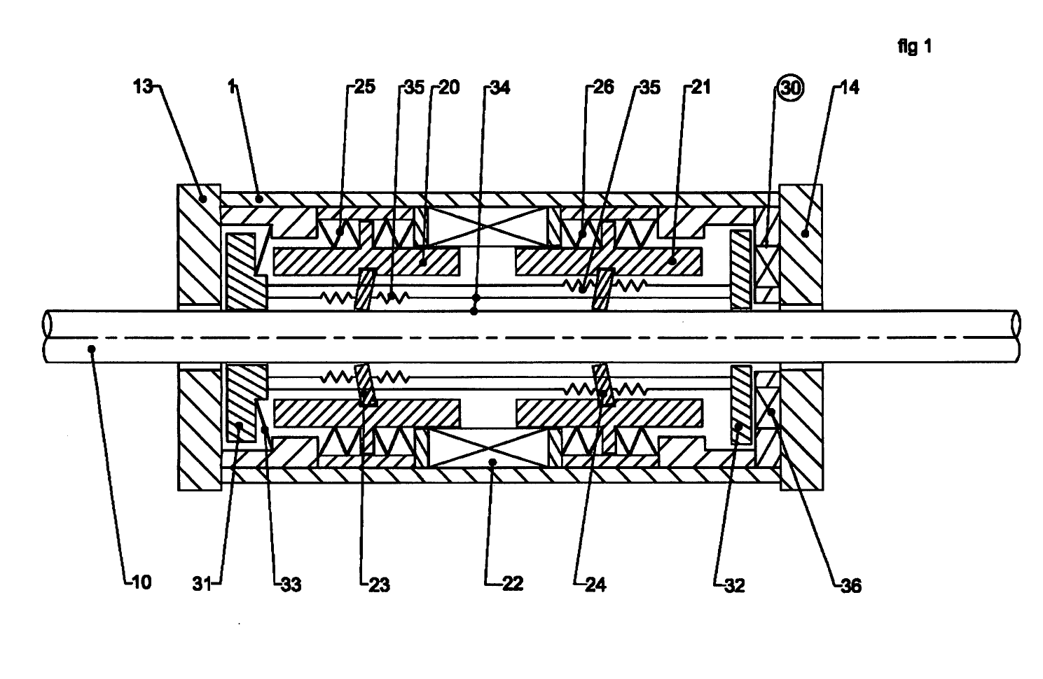

FIG. 1 illustrates schematically a method with direction-dependent clamping mechanism and energy buffering;

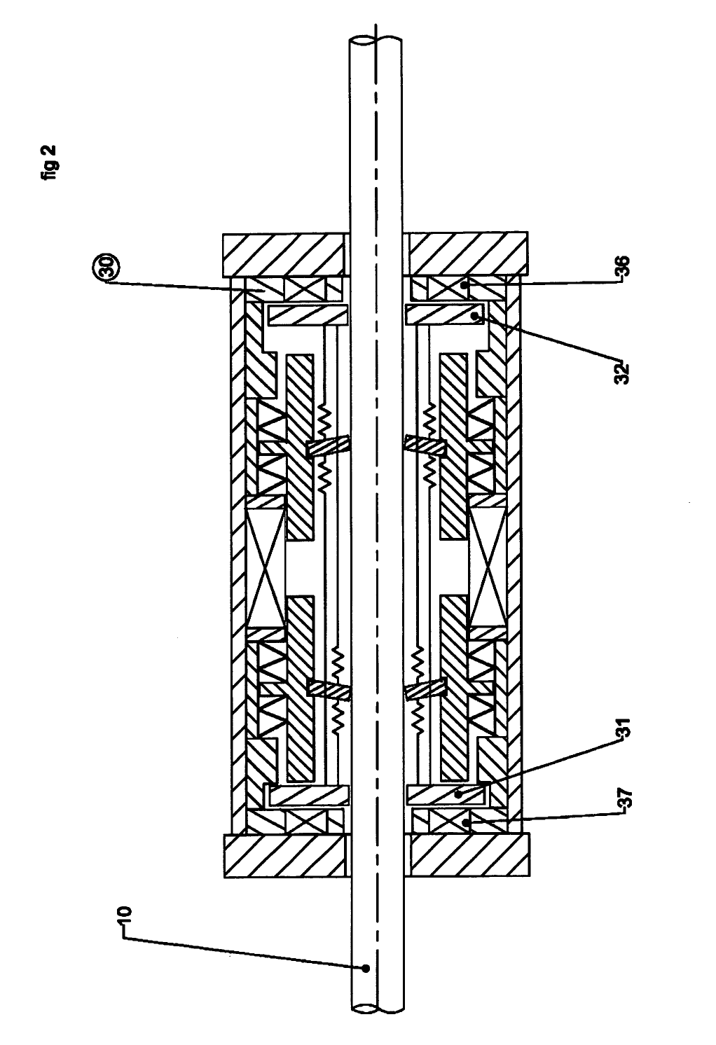

FIG. 2 shows an embodiment wherein the automatic braking is trivial;

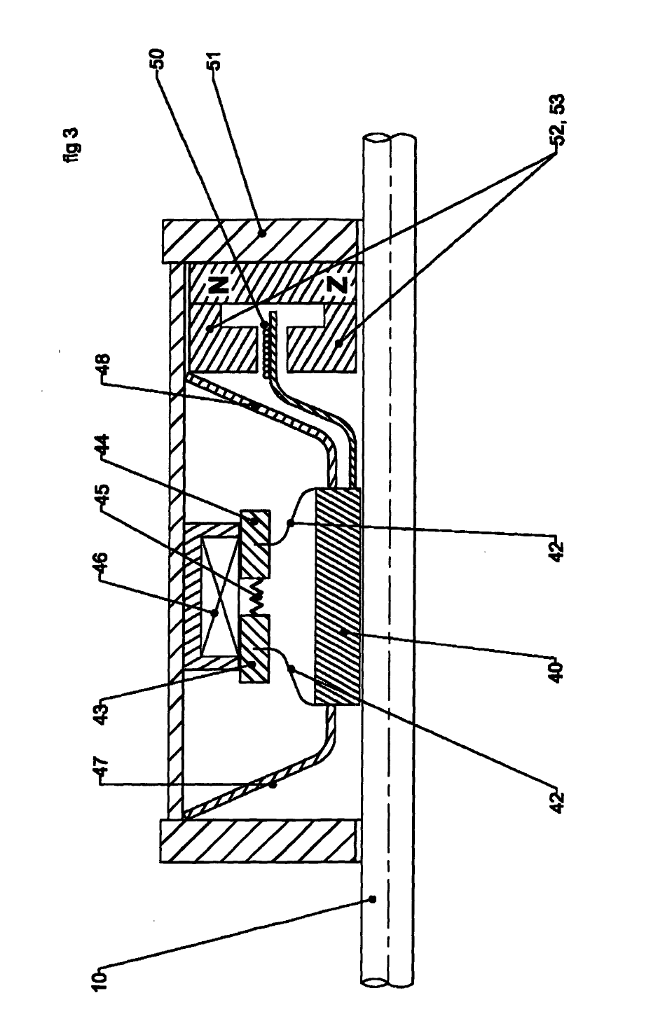

FIG. 3 shows an example of a bilateral clamping mechanism;

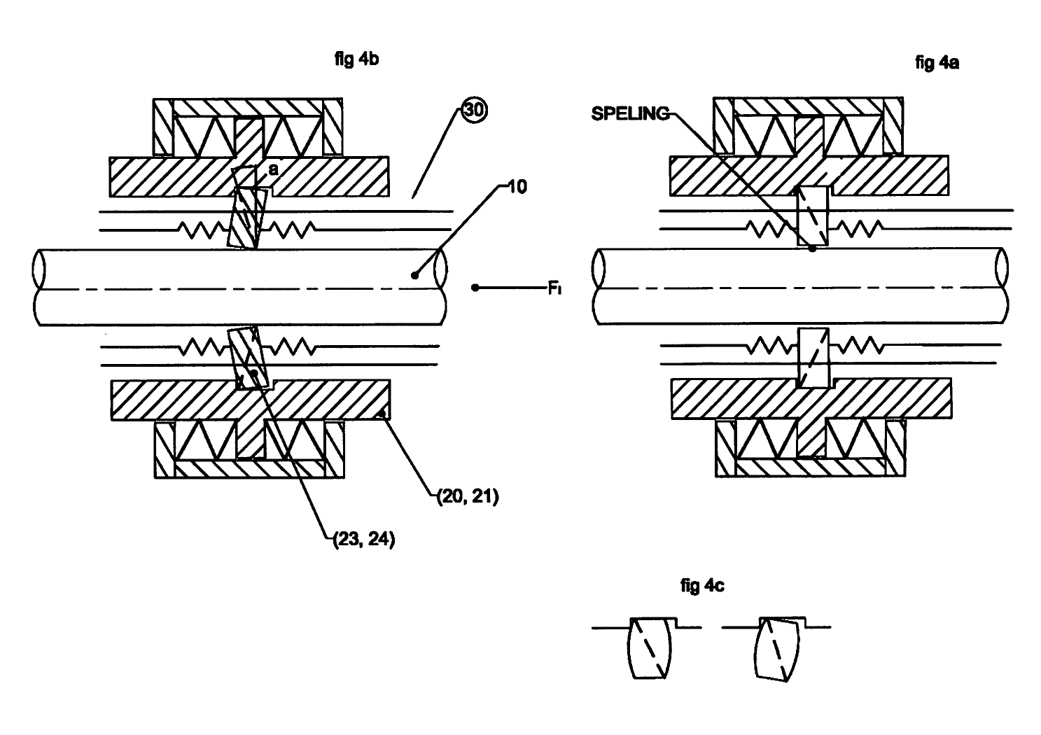

FIG. 4A shows energy-transmitting elements in the sliding position;

FIG. 4B shows energy-transmitting elements in the clamping position;

FIG. 4C shows an alternative form for the energy-transmitting elements;

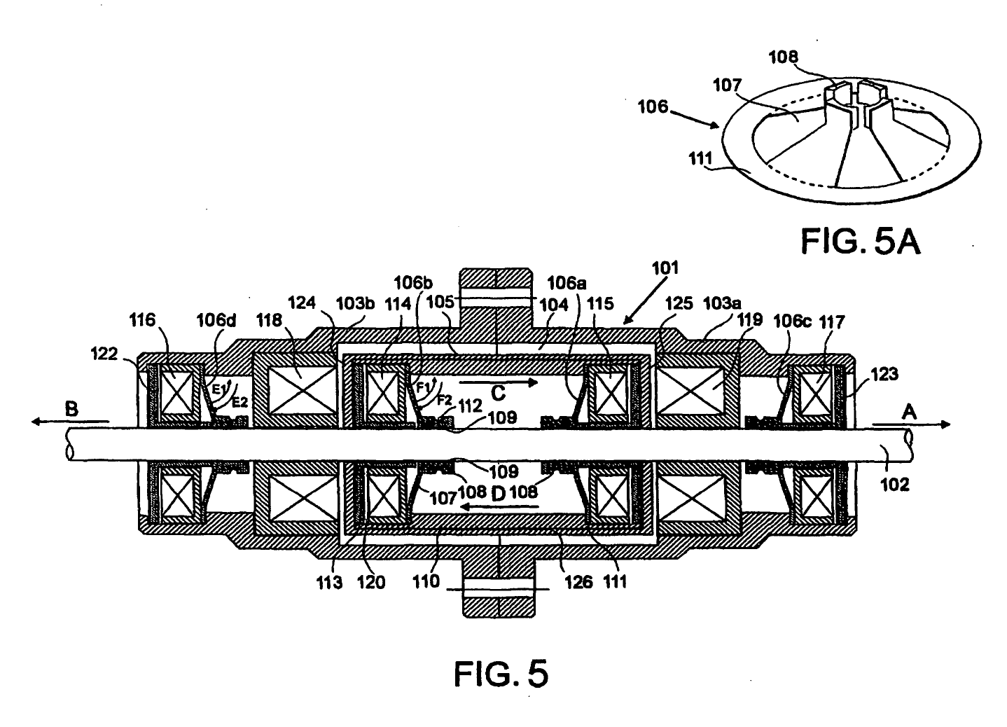

FIG. 5 shows a longitudinal section through an exemplary embodiment of a drive assembly according to the invention;

FIG. 5A shows a detail 105 of a drive part in the assembly of FIG. 5;

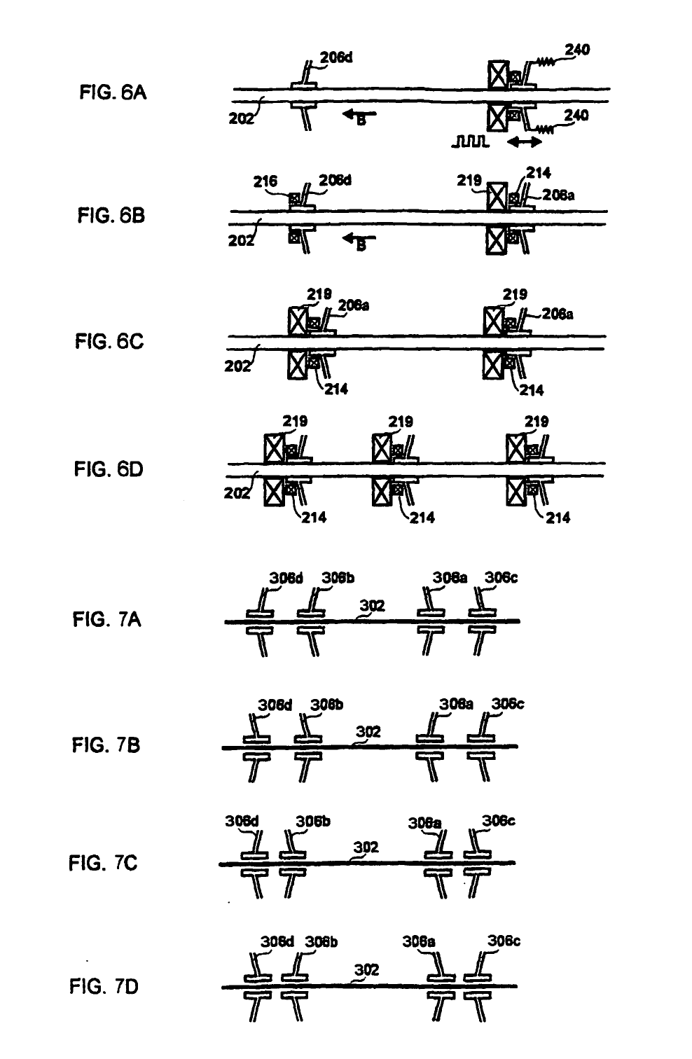

FIGS. 6A-D show several schematic arrangements of a drive assembly according to the invention for operation in one direction; and

FIGS. 7A-D show several schematic arrangements of a drive assembly according to the invention for double action.

FIG. 1 shows the assembly of a shaft 10 enclosed by a housing consisting of a sleeve 12 and two closing flanges 13, 14. Inside this housing are placed two or more intermediate bodies 20, 21, which are held in their preferred position by springs 25, 26. Situated inside the intermediate bodies is a direction-dependent clamping mechanism 23, 24 which is arranged acting in one direction by a setting mechanism 30. This setting mechanism 30 consists of two end plates 31, 32 which are held in a preferred position by a (cup) spring 33. In this position partly rigid 34 and partly flexible 35 connections ensure that the force-transmitting elements 23, 24 come to lie in the correct position for their function. This position can be changed, for instance by a magnetic device 36 which attracts end plate 32. The force-transmitting elements 23, 24 hereby come to lie in a different position (not shown here), whereby the direction of movement is reversed.

Driving takes place by activating the coil 22 in pulsed manner, whereby the intermediate bodies 20, 21 are drawn toward each other via the magnetic field and the gap therebetween is reduced. In FIG. 1, in the position drawn therein, the intermediate body 20 will move to the right, whereby the springs 25 associated with this intermediate body will be biased without shaft 10 hereby being influenced. During this action the intermediate body 21 will however be pulled to the left, whereby a force is transmitted onto shaft 10 via clamping mechanism 24. After this pulse the force for transmitting via intermediate body 21 will have disappeared, but the position-dependent force of the bias in springs 25 will transmit a remaining force onto shaft 10 via intermediate body 20. Due to the ending of the force on intermediate body 21 it will want to fall back into the preferred position in resonance. It will however overshoot due to the kinetic energy of the mass that is present, whereby a position-dependent force remains which is transmitted via clamping mechanism 24 to shaft 10. A high efficiency is hereby gained from brief activation of coil 22. This principle can of course be expanded with a plurality of intermediate bodies and coils which are actuated in a correct sequence and timing. A practically homogeneous movement, or driving, will thus be created. In the case coil 22 is replaced by a piezo-element, a movement in opposite direction will result, whereby the functions of both intermediate bodies are exchanged.

FIG. 2 shows the method of a similar disposition, although there is in this case a neutral position in the setting mechanism 30, whereby the device brakes automatically in both directions during power failure. When magnetic device 36 is activated the end plate 32 will be pulled to the right, whereby the direction of movement of shaft 10 will be to the left. This can be reversed by causing the magnetic device 37 to pull the end plate 31 to the left, whereby the direction of movement of shaft 10 will be to the right.

FIG. 3 shows a bilateral clamping mechanism. Shaft 10 is clamped herein by force-transmitting parts 40 which can be constructed from for instance four segments of a bush which encloses the shaft. These parts are pressed onto the shaft by wire-spring elements 41, 42 since rings 43, 44 are pressed axially apart under the influence of a spring 45. A very high transmission ratio of this spring force hereby results, which guarantees the clamping force on the shaft. Through the energizing of coil 46, the rings 43, 44 are however pulled toward each other. Owing to the manner of embodiment intended by the invention, this takes place in a manner not dependent on position. Wire-spring elements 41, 42 will hereby have to lie in a so-called S-bend, whereby the radius of the force-transmitting parts 40 will increase. These will hereby come to hang free of shaft 10, whereafter a relative movement between both parts 10, 40 can be realized in simple manner. The position of the parts 40 is preferably determined by springs 47, 48, whereby a position-dependent force is generated. These springs must be embodied such that a difference in radius of force-transmitting parts 40 can be absorbed without friction. In addition, a force can be superimposed on the clamping body, for instance by energizing the coil 50 situated within the magnetic field formed by permanent magnet 51 and anchors 52, 53, whereby shaft 10 can driven either directly or indirectly.

FIG. 4 shows the tilting principle according to the invention. Present here as energy or force-transmitting elements (clamping mechanism 23, 24) are elements which are placed between the shaft 10 for driving and an intermediate body 20, 21. These elements are characterized by a geometry which is such that, if these elements are placed with the height of the cross-section perpendicularly of the shaft, there is a small clearance between this element and the shaft (see FIG. A). This clearance ensures free axial movement of the shaft. These elements are pulled in a determined direction by means of setting mechanism 30. The diagonal of these elements hereby becomes clamped between the shaft and the intermediate body. This diagonal comes to lie such that an angle a is created, in which tan(α)<friction coefficient μ. Automatic braking hereby occurs when the shaft is loaded with a force F_{I}. The cross-section of these tilting elements (compare 12 to 16) does not have to be rectangular, but can for instance also be barrel-shaped, wherein both boundary surfaces are flattened, thereby creating the above-stated clearance (see FIG. C).

The linear drive assembly shown in FIG. 5 comprises a housing 101 in stationary position which encloses a shaft 102 for driving. Housing 101 comprises two housing parts 103a, 103b which are fixed to each other. Herein formed in the centre is a chamber 104 in which a housing 105 is received. At the ends the housing 105 has walls 124 and 125 of ferromagnetic material. These walls 124 and 125 can be mutually connected by means of connecting parts 126, wherein connecting parts 126 can also form an enclosing sleeve.

Placed in housing 105 at both longitudinal ends are electromagnetic decoupling coils 104 and 105, which are held at a fixed mutual distance by means of spacer parts 110 to which they are fixed. The distance of the coils relative to the nearby situated end walls 124 and 125 is constant. A radial clearance 113 is herein left between end walls 124, 125 and coils 114, 115, in which clearance T-shaped ferromagnetic anchors 120, 121 are received with their radial body. Clearances 113 allow a small displacement of anchors 120, 121 in axial direction.

Between spacers 110 and coils 114, 115 are clamped the radial outer ends 111 of drive parts 106, which are likewise substantially T-shaped with a drive shoe 108 located along shaft 102 and an arm 107 directed obliquely radially outward and toward the nearby coil. Shoes 108 are provided with an engaging surface 109 and provided on their opposite surface with a groove 112, in which an assemble ring 150 (FIG. 5A) can be arranged. The engaging parts 106 can together form an enclosing whole, for instance such as shown in FIG. 5A. They can further be manufactured from any suitable material, such as for instance plastic.

Further arranged in housing 101, axially after the receiving space 104, are two drive coils 118, 119 fixedly mounted in housing 101, and axially outside this another coil/drive part arrangement is then received at both ends in housing 101, these arrangements being comparable to those of coils 114, 115 and associated drive parts.

Preferably mounted fixedly herein on the housing are decoupling coils 116 and 117, which hold drive parts 106d and 106c fixedly clamped on housing 101 and leave a small space on the axial outer side to slidably receive the radial arms of anchors 122 and 123.

It will be understood that the diverse coils are connected to a suitable power supply and control means therefor.

When it is intended to move the shaft 102 in direction A, the drive coil 119 is energized whereby the ferromagnetic end wall 125 is attracted and housing 105 is thereby displaced in direction C. Coil 114 and the outer end 111 of arms 107 of engaging part 106b are hereby also displaced in direction C. A tilting moment in direction F2 will hereby be exerted on arms 107, which will thereby come to lie more radially. As a result the shoe 108 with engaging surface 109 will begin to exert a holding force on the surface of the shaft, and shaft 102 will immediately follow the movement of shoe 108, the 105 coil 114 and housing 105 in direction C, until end wall 125 moves against drive coil 119 or close thereto. In this movement the position of drive parts 106a is not important since these co-displace in direction C. This is however not the case for drive parts 106c since these are stationary with the housing. So as to enable a smooth transport of shaft 102 in the direction A, coil 117 is energized during the movement of housing 105 in direction C, whereby the T-shaped anchor 123 is displaced in the direction opposite direction A and then come to lie with the outer end of their horizontal legs against shoes 108, whereby a slight tilting of the arms 107 thereof takes place in direction H and the engaging surfaces 109 of shoes 108 press imperceptibly against surface 120 of shaft 102. When drive coil 119 is no longer energized, the energizing of coil 117 can also be stopped.

In order to drive the shaft 102 intermittently in the indicated direction C, the housing 105 must then be moved back 125 in the direction D. The shaft is herein held in place relative to housing 101 by the shoes 108 of drive parts 106d lying against the shaft on the left-hand side of housing 101 as seen in the drawing. With an already very small movement of shaft 102 to the left, shoes 108 would also be co-displaced, whereby arms 107 tilt in the direction F1 and the pressing force at the position of engaging surface 9 is increased.

When housing 105 moves in the direction D, shoes 108 of drive part 106b can slide to the left over the surface of shaft 102, although it is recommended to then also energize the coil 114, whereby the T-shaped anchor 120 is moved to the right as seen in the drawing, and the arms 107 of shoes 108 of drive parts 106b are tilted in the direction F1 in order to completely release the shaft 102. Coil 115 will in any case also be energized in order to achieve the same effect, i.e. a tilting in the direction G of arms 107 of drive parts 106A. Finally, housing 105 again comes to lie in a position furthest to the left, and energizing of coils 114 and 115 can be stopped and the movement 110 of housing 105 in the direction C can be started once again.

In this manner the shaft 102 can be displaced in direction A in very rapid, pulsating manner. Operation of this drive assembly according to the invention will be able to take place without disturbance through the use of electromagnetic means. The size of the assembly can herein be limited. Great drive forces can also be achieved in simple manner. In the case of power failure and/or switched-off drive—also in calamities—the drive will be able to block immediately. Compared to the prior art the action of the drive assembly according to the invention is very direct, and thereby safe and precise.

The drive assembly shown in FIG. 5 is suitable for double action. In that case the drive coil 118 is energized in order to attract the ferromagnetic end wall 124 to cause housing 105 to displace in direction D, wherein the drive parts 106a force the shaft 102 along in direction B with their shoes 108, and energizing of coil 116 via anchors 122 slightly releases the shoes 108 of drive parts 106d from the surface of shaft 102. During the return movement, in this case to the right of housing 105, coil 117 is not energized to cause shoes 108 of drive parts 106c to perform a blocking action, and in any case coil 114, and possibly also coil 115, can be energized again in order to prevent shaft 102 being able to move back in the direction A.

With this arrangement a double-action linear drive is provided in very compact manner.

FIG. 6A shows shaft 202 which can be driven in pulsating manner in direction B using a drive coil 219, which attracts a housing (not further shown) towards it in direction B, in which housing are arranged drive parts 206a for direct co-displacement, as was the case in FIG. 5. The housing is tensioned in an opposite direction by means of springs 240, so that the return movement of drive parts 206a takes place automatically. On the left are also shown drive parts 206d which are stationary and act as a clamping point to prevent the return movement of shaft 202, if this is desired.

In FIG. 6B is shown a comparable arrangement wherein coils 214 and 216 are however arranged close to drive parts 206a and 206d for the same reasons as in FIG. 5.

In FIG. 6C the assembly of drive part 206a, coil 214 and drive coil 219 is takes a double form, wherein it is possible to make provision for the control and decoupling to take place in counter-phase for a more uniform operation of shaft 202. FIG. 6D shows a similar, triple arrangement wherein control of the drive points and decouplings takes place in ⅓ phases. FIGS. 7A-D show in schematic manner, with only drive parts 306 a-c, a number of double-action arrangements, wherein it will be understood that the arrangement in FIG. 7B corresponds with that according to FIG. 5.

The linear drive according to the invention can be used at many locations. An elevator cage can thus be provided with a number of such drives, which engage on vertical fixed shafts. It is noted in this respect that, where mention is made in the foregoing and in the appended claims of driving a shaft, this term is intended in relative sense.

Other uses can be in mixing consoles of audio equipment, set-ups for opening windows, valve actuators, catering equipment, micro-drives, electrical locks (optionally with spring resetting), electrical bed adjustment, diverse (para)medical applications, fluid dispensing, scanners, printers and other computer equipment, valve control for fuel engines, photocopiers, printing equipment, production automation, aviation and space travel, robot technology, defence industry, brakes, clamps, clutches, diverse household and other consumer appliances and so on.

The linear drive according to the invention can be fitted at many locations due to the compact embodiment.

The invention is of course not limited to the shown and described preferred embodiments, but extends particularly to any possible combination of these embodiments, and extends generally to any embodiment which falls within the scope of the appended claims as seen in light of the foregoing description and drawings.

1. Method for relative driving of bodies on the basis of electromagnetic or piezo-electrical conversion of electricity into force and/or movement, characterized in that use is made of intermediate bodies for the conversion into mechanical energy.

2. Method as claimed in claim 1, characterized in that these intermediate bodies can be integrated with their surroundings, separated by resilient parts.

3. Method as claimed in claim 1 or 2, characterized in that the electrical energy is at least partially converted into buffered mechanical energy using these intermediate bodies before it is generated to the output shaft.

4. Method as claimed in any of the foregoing claims, characterized in that the intermediate bodies are suspended in buffers, for instance springs, whereby they will want to occupy a preferred position.

5. Method as claimed in any of the foregoing claims, characterized in that the intermediate bodies are suspended such that they can store kinetic energy.

6. Method as claimed in claim 5, characterized in that the intermediate bodies represent an amount of energy dependent on speed and position.

7. Method as claimed in any of the foregoing claims, characterized in that a plunger or (part of) a disc is as intermediate body which is arranged round or inside a body for driving.

8. Method as claimed in claim 7, characterized in that an intermediate body is actuated in the non-clamping direction, whereby energy is buffered before it is transferred to the body for driving.

9. Method as claimed in any of the foregoing claims, characterized in that when an intermediate body is actuated a reaction force is generated onto one or more other bodies.

10. Method as claimed in any of the foregoing claims, characterized in that when the electromechanical or electromagnetic converter is energized a force not dependent on position is obtained between two or more (parts of) intermediate bodies.

11. Method as claimed in claim 9 or 10, characterized in that when an intermediate body is actuated a reaction force is generated onto another intermediate body, wherein this force is transferred to the body for driving.

12. Method as claimed in any of the foregoing claims for coupling the intermediate body and the body for driving, characterized in that the energy-transferring element consists of a plurality of components movable independently of each other.

13. Method as claimed in claim 12, characterized in that the energy-transferring element consists of one component which distinguishes resiliently pivoting elements.

14. Method as claimed in claim 12 or 13, characterized in that the energy-transferring element does not slip or roll relative to the encasing bodies in the direction of energy transfer.

15. Method as claimed in claim 12, 13 or 14, characterized in that the direction of possible energy transfer changes due to a change in position of the energy-transferring elements.

16. Method as claimed in claim 15, characterized in that in a neutral position the energy-transferring element can move freely over the body for driving, but that the geometry causes tilting through angular displacement, and thus transfer of energy.

17. Method as claimed in any of the foregoing claims for coupling the intermediate body and the body for driving, characterized in that the energy-transferring element clamps in both directions.

18. Method as claimed in claim 17, characterized in that this energy-transferring element can be releasing or clamping in two positions relative to the body for driving.

19. Method as claimed in claim 17 or 18, characterized in that actuation is possible between these two positions.

20. Method as claimed in any of the foregoing claims, characterized in that the force, speed and power can be varied by means of the manner of actuation.

21. Linear drive assembly for a shaft or other elongate body, comprising engaging means for co-displacing engagement of the shaft and the like, as well as displacing means forming a moving whole with the engaging means for displacing the engaging means in driving direction between a non-engaging or slipping position and an engaging or shaft-co-displacing position, further comprising means for displacing the displacing means in driving direction.

22. Drive assembly as claimed in claim 21, wherein the displacing means are adapted to exert a pushing force on the engaging means in the driving direction.

23. Drive assembly as claimed in claim 21 or 22, wherein the engaging means comprise shoes provided with engaging surfaces which engage the shaft, as well as preferably resilient arms which extend radially counter to the driving direction of the shoes and which connect the shoes to the displacing means.

24. Drive assembly as claimed in claim 23, wherein the arms are connected movably, in particular rotatably or tiltably, to the displacing means.

25. Drive assembly as claimed in claim 23 or 24, wherein the shoes are at all times held close to the shaft, preferably by means of a belt.

26. Drive assembly as claimed in any of the foregoing claims, further provided with means, preferably at least one electromagnet, for displacing the displacing means.

27. Drive assembly as claimed in claim 26, wherein the displacing means and drive means are received in a holder, such as a housing, which is disposed slidably in shaft direction.

28. Drive assembly as claimed in claim 26, wherein said means comprise a ferromagnetic end plate in combination with an electromagnet.

29. Drive assembly as claimed in claim 26, wherein said means comprise a (freely moving) coil in a permanent magnetic field.

30. Drive assembly as claimed in claim 27, further comprising means for moving back the holder, in particular the displacing means, counter to the drive direction relative to the shaft.

31. Drive assembly as claimed in claim 28, wherein the means for moving back comprise a spring.

32. Drive assembly as claimed in claim 28, wherein the means for moving back operate electromagnetically.

33. Drive assembly as claimed in any of the foregoing claims, further provided with relatively stationary means for retaining the shaft in a return direction.

34. Drive assembly as claimed in claim 31, wherein the retaining means comprise shoes and arms comparable to the drive means.

35. Drive assembly as claimed in claim 32, wherein the retaining means act passively on the shaft, wherein means are present for de-activating the retaining means, preferably electromagnetic means.

36. Drive assembly as claimed in claim 33, wherein the means for de-activating comprise means for reducing the contact pressure of the shoes against the shaft.

37. Device comprising two drive assemblies as claimed in any of the foregoing claims, wherein the drive assemblies are disposed for moving the shaft in opposite directions.

38. Device as claimed in claim 35, further provided with means for de-activating the engaging means, preferably electromagnetic means, during a return stroke of the shaft and the like.

39. Device as claimed in claims 35 and 36, wherein the means for de-activating the engaging means are placed outside the holder according to claim 7.

40. Device as claimed in any of the foregoing claims, wherein the means for de-activating the engaging means preferably act electromagnetically in one direction and by means of a spring in another direction.

41. Device as claimed in claim 35, wherein the holder is buffered in two directions by a spring.

42. Device as claimed in claim 35, wherein the drive means are buffered in both directions by springs.

43. Device comprising two or more devices as claimed in claim 35, which are actuated in mutually adapted phases in order to provide a more uniform movement.

44. Device as claimed in any of the foregoing claims, wherein the actuation of the drive means is controlled such that a homogeneous, prescribed force or displacement is realized.

45. Linear drive assembly for a shaft or other elongate body, comprising engaging means for co-displacing engagement of the shaft and the like, further comprising controllable electromagnetically acting means for displacing the engaging means in driving direction.

46. Drive assembly as claimed in any of the foregoing claims, further comprising controllable electromagnetically acting means for releasing the drive means from the shaft.

47. Drive assembly as claimed in any of the foregoing claims, further comprising controllable electromagnetically acting means for fixing the shaft.

48. Device as claimed in any of the foregoing claims, further provided with a position sensor.

49. Device as claimed in any of the foregoing claims, further provided with a position sensor integrated into the shaft.

50. Device as claimed in any of the foregoing claims, further comprising electronic or other means for actuating the engaging and drive means according to the foregoing claims, comprising analog, digital, fuzzy logic or a neuronal network, or a combination of these means.

51. Device as claimed in any of the foregoing claims, wherein electromagnetic means are replaced by an alternative, preferably piezo-actuators.
